(19) United States
(12) Patent Application Publication
(10) Pub. No.: US 2026/0262157 A1
(43) Pub. Date: Sep. 3, 2026

(54) HEAT SINK ASSEMBLY WITH MOVABLE PINS WITHIN A SUBSTRATE PLATE TO THERMALLY CONNECT A MATERIAL WITH A THERMAL INTERFACE

(71) Applicant: Raytheon Company, Arlington, VA (US)

(72) Inventors: Nicholas Gonzalez, Vail, AZ (US); Alfa Lopez, Vail, AZ (US)

(21) Appl. No.: 19/068,713

(22) Filed: Mar. 3, 2025

(51) Int. Cl. H05K 1/02

(52) U.S. Cl. CPC H05K 1/0203

(57) ABSTRACT

A heat sink assembly for thermally connecting a material to a thermal interface, having: a substrate plate having a bottom surface, a top surface and a thickness defined between the bottom and top surfaces, the substrate plate defines apertures that extend between the bottom and top surfaces; and conductive pins having bottom ends and top ends and a length defined between the bottom and top ends, wherein the length of the conductive pins is greater than the thickness of the substrate plate, and wherein the conductive pins are disposed in the apertures so that the bottom ends extend below the bottom surface to contact the material, wherein the conductive pins are configured for being independently moved within the apertures to conform with contours defined along the material when the substrate plate is against the thermal interface, to thereby provide a uniform thermal connection between the material and the thermal interface.

### BACKGROUND

The embodiments are directed to heat sink and more specifically to a heat sink assembly with movable pins that may be utilized to thermally connect a material with a thermal interface.

Circuit card assemblies (CCAs) are typically mounted in a housing. The housing in which the CCA is mounted can often serve as the primary heat sink to transport heat away from CCA and related components. Relatively larger components of the CCA may be cooled with a thermal pad, which allows for direct coupling with the housing. Thermal pads may require compression to be effective and usually have a relatively low thermal conductivity due to their composition, e.g., less than 5 W/mK. While this may be adequate to cool one component of a CCA, it may be less effective for managing heat in a CCA having components of different heights where a board level cooling solution is required.

### BRIEF SUMMARY

Disclosed is a heat sink assembly for thermally connecting a material to a thermal interface, the assembly including: a substrate plate having a bottom surface, a top surface and a thickness defined between the bottom and top surfaces, wherein the substrate plate defines apertures that extend between the bottom and top surfaces; and conductive pins having bottom ends and top ends and a length defined between the bottom and top ends, wherein the length of the conductive pins is greater than the thickness of the substrate plate, and wherein the conductive pins are disposed in the apertures so that the bottom ends extend below the bottom surface to contact the material, wherein the conductive pins are configured for being independently moved within the apertures to conform with contours defined along the material when the substrate plate is against the thermal interface, to thereby provide a uniform thermal connection between the material and the thermal interface.

In addition to one or more aspects of the assembly or as an alternate, the material includes electronics.

In addition to one or more aspects of the assembly or as an alternate, the top ends of the conductive pins are trimmed flush with the top surface of the substrate plate.

In addition to one or more aspects of the assembly or as an alternate, the substrate plate is formed of a conductive material.

In addition to one or more aspects of the assembly or as an alternate, the substrate plate is formed of aluminum or copper.

In addition to one or more aspects of the assembly or as an alternate, the conductive pins are formed of solder.

In addition to one or more aspects of the assembly or as an alternate, the substrate plate is aluminum or copper and the conductive pins are formed of a material that differs from the substrate plate.

Disclosed is a system, including: a material; a thermal interface spaced apart from the material; and a heat sink assembly disposed between the material and the thermal interface, the heat sink assembly configured for thermally connecting material to a thermal interface, the heat sink assembly including: a substrate plate having a bottom surface, a top surface and a thickness defined between the bottom and top surfaces, wherein the substrate plate defines apertures that extend between the bottom and top surfaces; and conductive pins having bottom ends and top ends and a length defined between the bottom and top ends, wherein the length of the conductive pins is greater than the thickness of the substrate plate, and wherein the conductive pins are disposed in the apertures so that the bottom ends extend below the bottom surface to contact the material, wherein the conductive pins are configured for being independently moved within the apertures to conform with contours defined along the material when the substrate plate is against the thermal interface, to thereby provide a uniform thermal connection between the material and the thermal interface, wherein the bottom ends of the conductive pins are against the material and the substrate plate is against the thermal interface.

In addition to one or more aspects of the system or as an alternate, one or more of the material, the conductive pins, the substrate plate, and the thermal interface, are coated with a conformal coating.

In addition to one or more aspects of the system or as an alternate, the conformal coating is a polymeric film.

In addition to one or more aspects of the system or as an alternate, the material includes a printed circuit board (PCB) and a first electrical component secured to the PCB.

In addition to one or more aspects of the system or as an alternate, the material includes a plurality of electrical components secured to the PCB, including the first electrical component and a second electrical component is thicker than the first electrical component, and the conductive pins extending between the first electrical component and the thermal interface are longer than the conductive pins extending between the second electrical component and the thermal interface to accommodate a difference in thickness between the first and second electrical components.

In addition to one or more aspects of the system or as an alternate, the thermal interface is a thermal pad.

In addition to one or more aspects of the system or as an alternate, the thermal pad has a thermal conductivity that is less than a thermal conductivity of the conductive pins or the substrate plate.

In addition to one or more aspects of the system or as an alternate, the system includes: a housing having a bottom housing portion and a top housing portion, wherein: the PCB is secured within the housing and to the bottom housing portion; and the thermal interface is defined by the top housing portion, or the thermal interface is secured within the housing, to the top housing portion.

In addition to one or more aspects of the system or as an alternate, the system includes a thermal pad secured within the housing, to the top housing portion, to define the thermal interface.

In addition to one or more aspects of the system or as an alternate, the top housing portion is thermally conductive.

In addition to one or more aspects of the system or as an alternate, the system includes an external heat sink secured to the top housing portion, such that the external heat sink is thermally coupled to the thermal interface.

In addition to one or more aspects of the system or as an alternate, the external heat sink is a convective or conductive heat sink.

### BRIEF DESCRIPTION OF THE SEVERAL VIEWS OF THE DRAWINGS

The subject matter which is regarded as the invention is particularly pointed out and distinctly claimed in the claims at the conclusion of the specification. The foregoing and other features and advantages of the invention are apparent from the following detailed description taken in conjunction with the accompanying drawings in which:

FIG. 1 shows a side view of a heat sink assembly according to an embodiment, having a substrate plate with apertures and conductive pins within the apertures;

FIG. 2 shows a top view of the heat sink assembly, where the conductive pins are omitted for simplicity;

FIG. 3 shows an electronics assembly in a housing according to a nonlimiting embodiment, having electronics within a bottom end of the housing, a thermal pad within a top end of the housing, and the heat sink assembly disposed between the electronics and the thermal pad; and

FIG. 4 shows a heat sink assembly applied to a hot body of a generic shape.

### DETAILED DESCRIPTION

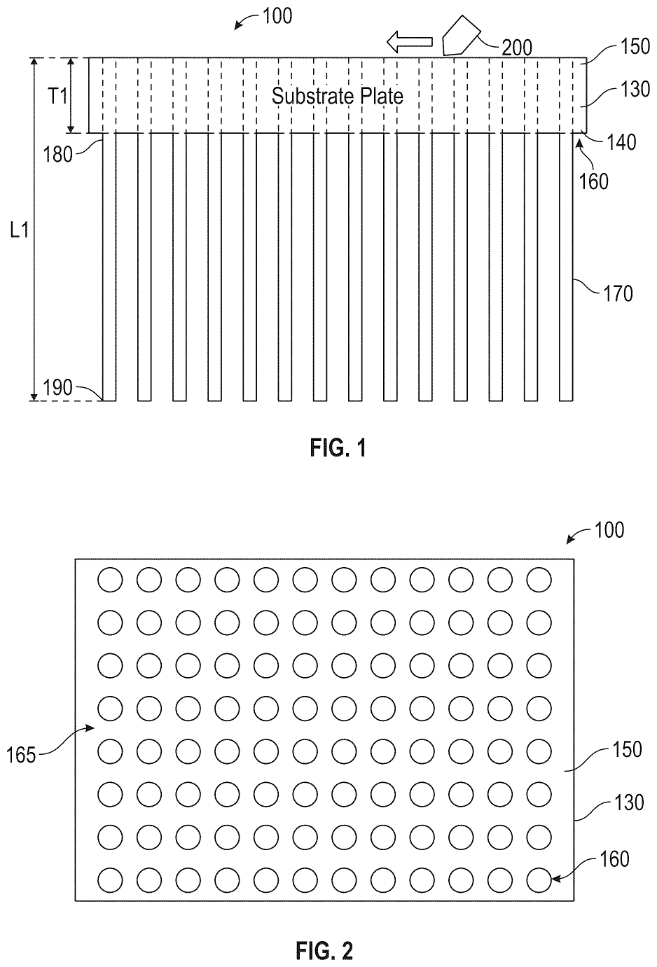

Turning to FIGS. 1-3, a heat sink assembly 100 is disclosed for thermally connecting a material, which may be electronics 110, to a thermal interface as more fully described below. The assembly 100 includes a substrate plate 130 having a bottom surface 140, a top surface 150 and a thickness T1 defined between the bottom and top surfaces 140, 150. The substrate plate 130 defines apertures 160 that extend between the bottom and top surfaces 140, 150. In a non-limiting embodiment, each of the apertures 160 define a cylindrical shape. In some embodiments, there may be thousands of apertures 160 in the substrate plate 130. The apertures 160 may be arranged in a rectangular grid pattern 165 (FIG. 2).

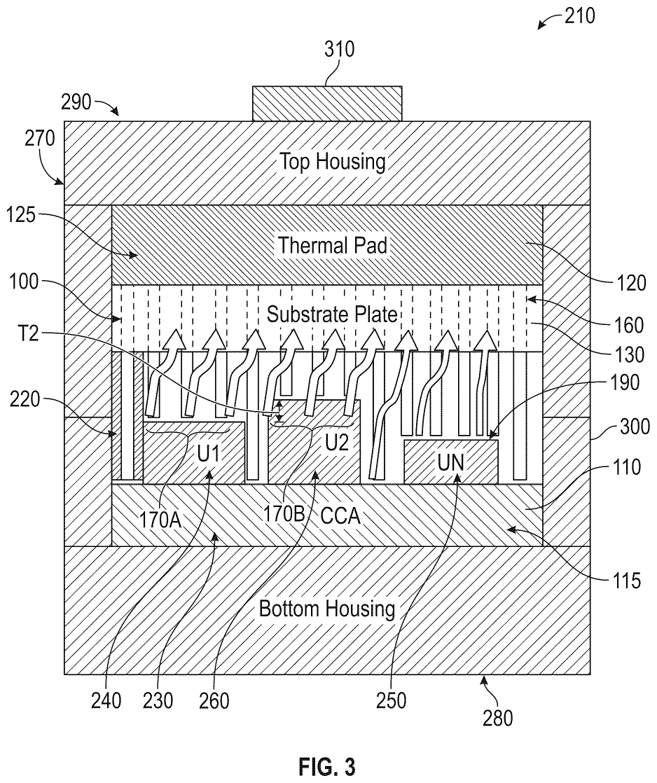

Conductive pins 170 respectively have bottom ends 180 and top ends 190, and a length L1 defined between the bottom and top ends 180, 190. The length L1 of the conductive pins 170 is greater than the thickness T1 of the substrate plate 130. The conductive pins 170 are disposed in ones of the apertures 160 so that the bottom ends 180 extend below the bottom surface 140 of the substrate plate 130 to contact the electronics 110 when the top surface 150 of the substrate plate 130 is against the thermal interface 120 (FIG. 3).

The conductive pins 170 are configured for being independently moved within the apertures 160, i.e., in the thickness direction for the substrate plate 130, to conform with contours defined along the electronics 110 when the substrate plate 130 is against the thermal interface 120 (FIG. 3). Top ends 180 of the conductive pins 170 that extend above the top surface 150 of the substrate plate 130 may be trimmed flush with the top surface 150 of the substrate plate 130 with a solder pen 200 (FIG. 1). This configuration provides a uniform thermal connection between the electronics 110 and the thermal interface 120.

In one embodiment, the substrate plate 130 is formed of a conductive material. The substrate plate 130 may be formed of aluminum or copper. The conductive pins 170 may be formed of solder. The substrate plate 130 and the conductive pins 170 may be formed of a same material as each other.

As shown in FIG. 2, the shape of the substrate plate 130, in the top view, is rectangular. However, this is not intended on limiting the scope of the embodiments. The shape of the substrate plate 130 may conform to the available space, depending on the application.

Turning to FIG. 3, an electronics system 210 may include the electronics 110, a thermal interface 120 spaced apart from the electronics 110, and the heat sink assembly 100 disposed between the electronics 110 and the thermal interface 120, where the use of the thermal interface 120 is optional. As shown in FIG. 3, the bottom ends 190 of the conductive pins 170 are against the electronics 110 and the substrate plate 130 is against the thermal interface 120.

In addition, or alternatively the in the presence of or desire for a thermal interface, the substrate plate and thermal interface may be compressed together.. The electronics 110, the conductive pins 170, the substrate plate 130 or the thermal interface 120, or each of these elements of the disclosed embodiment, may be coated with a conformal coating 220. In one embodiment, the conformal coating 220 is a polymeric film.

The electronics 110 may be a circuit card assembly (CCA) 115 that may include a printed circuit board (PCB) 230 and a first electrical component 240 secured to the PCB 230. In one embodiment, a plurality of electrical components 250 may be secured to the PCB 230, including the first electrical component 240, e.g., and a second electrical component 260 that is thicker than the first electrical component 240 by a second thickness T2. With this configuration, conductive pins 170A extending between the first electrical component 240 and the thermal interface 120 are longer than conductive pins 170B extending between the second electrical component 260 and the thermal interface 120 to accommodate the difference in thickness T2 between the first and second electrical components 240, 260. This configuration is obtained, as indicated, by trimming portions of the conductive pins 170 that extend out of the top surface 150 of the substrate plate 130 with the solder pen 200. As can be appreciated, the shape of the substrate plate 130, in the top view, may conform with the shape of the CCA 115.

In one embodiment, the thermal interface 120 is a thermal pad 125. The thermal pad 125 may have a thermal conductivity that is less than a thermal conductivity of the conductive pins 170 or the substrate plate 130. For example, the thermal conductivity of the pad 125 may be between two and 5 W/m^2*K. Most solders a tin-lead alloy, meaning they are some percentage tin and some percentage lead. the conductivity of tin-lead solders ranges for 60-130 W/mK depending on composition.

The electronics system 210 may have a housing 270. The housing 270 may have a bottom housing portion 280 and a top housing portion 290, with sidewalls 300 extending between the bottom and top housing portions 280, 290. The PCB 230 may be secured within the housing 270, to the bottom housing portion 280. The thermal interface 120 may be defined by the top housing portion 290. That is, the housing 270 may be at least in part manufactured from a thermally conductive material. Or the thermal interface 120 may be the thermal pad 125, secured within the housing 270, to the top housing portion 290.

In one embodiment, an external heat sink 310 is secured to the top housing portion 290, such that the external heat sink 310 may be thermally coupled to the top housing 270. The external heat sink 310 may be a convective heat transfer mechanism, such as a fan, or a conductive heat sink, such as a cooling plate.

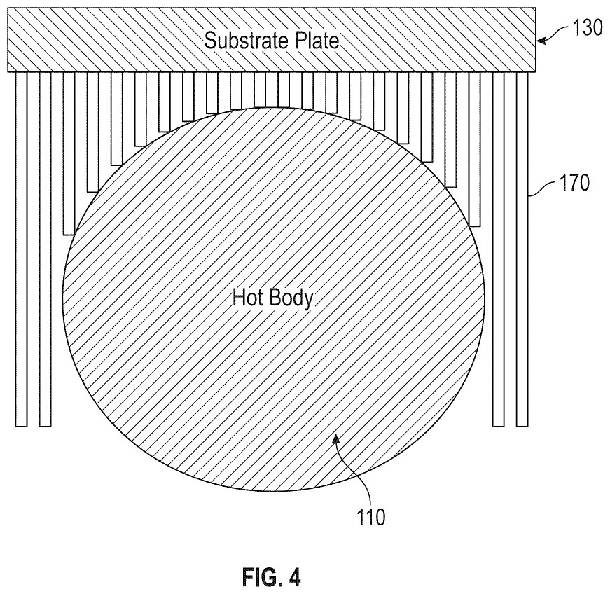

As shown in FIG. 4, a material 110, e.g., a hot body, may have any shape, though a circular shape is shown, e.g., with a spherically shaped material 110. The pins 170 extend downwardly from the substrate plate 130 and are trimmed to confirm with the shape of the material 110. As indicated, the material 110 maybe electronics, but that is not intended on limiting the scope or application of the embodiments.

The embodiments provide a substrate plate 130 with pins 170 that can slide freely through apertures 160 in the plate 130. The plate 130 may be machined so that it matches the shape of the CCA 115. The substrate plate 130 may be positioned in the housing 270, and the positioning of the pins 170 may confirm to the configuration of the CCA 115 due to the presence of components such as electrical components 240 with different heights. The pins 170 can then be cut with a solder pen 200 to ensure they are coupled to the housing 270. The presence of the pins 170 and their contact with areas on the substrate plate 130 and CCA 115 provide a conduction path and couple the housing 270 and the CCA 115 in a more efficient way than a pad 120, or thermal putty, may alone. Preferably, the embodiments are provided as a dry process rather than a wet process. The presence of hundreds, or thousands of pins 170, each having a relatively small diameter, can increase an efficiency of the housing 270 acting as a heat sink. The heat sink assembly 100 may be relatively easily removed in case of a failure of the CCA 115. The terminology used herein is for the purpose of describing particular embodiments only and is not intended to be limiting of the present disclosure. The term “about” is intended to include the degree of error associated with measurement of the particular quantity and/or manufacturing tolerances based upon the equipment available at the time of filing the application. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

Those of skill in the art will appreciate that various example embodiments are shown and described herein, each having certain features in the particular embodiments, but the present disclosure is not thus limited. Rather, the present disclosure can be modified to incorporate any number of variations, alterations, substitutions, combinations, sub-combinations, or equivalent arrangements not heretofore described, but which are commensurate with the scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

What is claimed is:

1. A heat sink assembly for thermally connecting a material to a thermal interface, the assembly comprising:
a substrate plate having a bottom surface, a top surface and a thickness defined between the bottom and top surfaces, wherein the substrate plate defines apertures that extend between the bottom and top surfaces; and
conductive pins having bottom ends and top ends and a length defined between the bottom and top ends, wherein the length of the conductive pins is greater than the thickness of the substrate plate, and wherein the conductive pins are disposed in the apertures so that the bottom ends extend below the bottom surface to contact the material,
wherein the conductive pins are configured for being independently moved within the apertures to conform with contours defined along the material when the substrate plate is against the thermal interface, to thereby provide a uniform thermal connection between the material and the thermal interface.

2. The assembly of claim 1, wherein the material comprises electronics.

3. The assembly of claim 1, wherein the top ends of the conductive pins are trimmed flush with the top surface of the substrate plate.

4. The assembly of claim 1, wherein the substrate plate is formed of a conductive material.

5. The assembly of claim 1, wherein the substrate plate is formed of aluminum or copper.

6. The assembly of claim 1, wherein the conductive pins are formed of solder.

7. The assembly of claim 1, wherein the substrate plate is aluminum or copper and the conductive pins are formed of a material that differs from the substrate plate.

8. A system, comprising:
a material;
a thermal interface spaced apart from the material; and
a heat sink assembly disposed between the material and the thermal interface, the heat sink assembly configured for thermally connecting material to a thermal interface,
the heat sink assembly including:
a substrate plate having a bottom surface, a top surface and a thickness defined between the bottom and top surfaces, wherein the substrate plate defines apertures that extend between the bottom and top surfaces; and
conductive pins having bottom ends and top ends and a length defined between the bottom and top ends, wherein the length of the conductive pins is greater than the thickness of the substrate plate, and wherein the conductive pins are disposed in the apertures so that the bottom ends extend below the bottom surface to contact the material,
wherein the conductive pins are configured for being independently moved within the apertures to conform with contours defined along the material when the substrate plate is against the thermal interface, to thereby provide a uniform thermal connection between the material and the thermal interface,
wherein the bottom ends of the conductive pins are against the material and the substrate plate is against the thermal interface.

9. The system of claim 8, wherein one or more of the material, the conductive pins, the substrate plate, and the thermal interface, are coated with a conformal coating.

10. The system of claim 9, wherein the conformal coating is a polymeric film.

11. The system of claim 8, wherein the material comprises a printed circuit board (PCB) and a first electrical component secured to the PCB.

12. The system of claim 11, wherein
the material comprises a plurality of electrical components secured to the PCB, including the first electrical component and a second electrical component is thicker than the first electrical component, and
the conductive pins extending between the first electrical component and the thermal interface are longer than the conductive pins extending between the second electrical component and the thermal interface to accommodate a difference in thickness between the first and second electrical components.

13. The system of claim 12, wherein the thermal interface is a thermal pad.

14. The system of claim 13, wherein the thermal pad has a thermal conductivity that is less than a thermal conductivity of the conductive pins or the substrate plate.

15. The system of claim 12, further comprising:
a housing having a bottom housing portion and a top housing portion,
wherein:
the PCB is secured within the housing and to the bottom housing portion; and
the thermal interface is defined by the top housing portion, or the thermal interface is secured within the housing, to the top housing portion.

16. The system of claim 15, comprising a thermal pad secured within the housing, to the top housing portion, to define the thermal interface.

17. The system of claim 15, wherein the top housing portion is thermally conductive.

18. The system of claim 15, comprising an external heat sink secured to the top housing portion, such that the external heat sink is thermally coupled to the thermal interface.

19. The system of claim 18, wherein the external heat sink is a convective or conductive heat sink.
